(19) United States
(12) Patent Application Publication
(10) Pub. No.: US 2023/0123633 A1
(43) Pub. Date: Apr. 20, 2023

(54) SYSTEMS AND METHODS FOR DYNAMIC CONTROL OF COOLING FLUID FLOW IN AN EPITAXIAL REACTOR FOR SEMICONDUCTOR WAFER PROCESSING

(71) Applicant: GlobalWafers Co., Ltd., Hsinchu (TW)

(72) Inventors: Pier Giulio Poy, Novara (IT); Giuseppe Finotti, Borgolavezzaro (IT); Silvano Gamarra, Somma Lombardo (IT)

(21) Appl. No.: 17/934,875

(22) Filed: Sep. 23, 2022

Related U.S. Application Data
(60) Provisional application No. 63/262,574, filed on Oct. 15, 2021.

(51) Int. Cl. H01L 21/67; H01L 21/02

(52) U.S. Cl. CPC H01L 21/67109; H01L 21/0262

(57) ABSTRACT

An epitaxial reactor system includes a reactor, a cooling circuit, and a controller. The reactor includes a reaction chamber having an upper wall and a lower wall, an upper module positioned above the upper wall, and a lower module positioned below the lower wall. The cooling circuit includes a blower to circulate fluid within the upper module and the lower module and a damper selectably positioned to control an amount of fluid flow provided to each of the upper module and the lower module. The damper is coupled to a damper actuator that adjusts a position of the damper. The system further includes a controller configured to: receive epitaxial process information associated with the reactor, generate a blower output and a damper position output based on the epitaxial process information, transmit the blower output to the blower, and transmit the damper position output to the damper actuator.

### CROSS-REFERENCE TO RELATED APPLICATION

This application claims priority to U.S. Provisional Patent Application No. 63/262,574, filed Oct. 15, 2021, the disclosure of which is hereby incorporated by reference in its entirety.

### FIELD

The field relates generally to systems and methods for semiconductor wafer processing, and more particularly to systems and methods for dynamic control of cooling fluid flow in an epitaxial reactor.

### BACKGROUND

Epitaxial chemical vapor deposition (CVD) is a process for growing a thin layer of material on a semiconductor wafer so that the lattice structure is identical to that of the wafer. Epitaxial CVD is widely used in semiconductor wafer production to build up epitaxial layers such that devices can be fabricated directly on the epitaxial layer. The epitaxial deposition process begins by introducing a cleaning gas, such as hydrogen or a hydrogen and hydrogen chloride mixture, to a front surface of the wafer (i.e., a surface facing away from the susceptor) to pre-heat and clean the front surface of the wafer. The cleaning gas removes native oxide from the front surface, permitting the epitaxial silicon layer to grow continuously and evenly on the surface during a subsequent step of the deposition process. The epitaxial deposition process continues by introducing a vaporous silicon source gas, such as silane or a chlorinated silane, to the front surface of the wafer to deposit and grow an epitaxial layer of silicon on the front surface. A back surface opposite the front surface of the susceptor may be simultaneously subjected to hydrogen gas. The susceptor, which supports the semiconductor wafer in the deposition chamber during the epitaxial deposition, is rotated during the process to allow the epitaxial layer to grow evenly.

Epitaxial CVD is performed in a semiconductor wafer reactor. Conventional reactors include a reactor chamber in which the wafer is positioned on the susceptor. The reactor chamber has a chamber body with upper and lower walls made of a suitable material (e.g., quartz) which define the interior volume in which the wafer and susceptor are located. The reactor includes one or more temperature sensors (e.g., optical pyrometers) to monitor the temperature during the process, which may suitably be located outside the reactor chamber due to the high temperatures reached during the process. The upper and lower walls are suitably transparent to allow the optical pyrometers to obtain non-contact temperature measurements of components within the reactor chamber (e.g., the wafer or susceptor).

During the epitaxial deposition process, the wafer and susceptor are typically heated using heating elements located outside the reactor chamber that provide heat to the reactor chamber through the upper and lower walls, which causes the upper and lower walls to also increase in temperature. Exposure of the walls to the epitaxial deposition process gases may result in the formation of deposit films on the heated walls. Some reactors may be designed to prevent exposure of the lower wall to the process gases, but the upper wall proximate the front wafer surface remains exposed. As such, the higher temperature of the upper wall during the deposition process causes a deposit film to form thereon, which deteriorates the transparency of the upper wall and may result in inaccurate temperature measurements from the optical pyrometer(s) that obtain temperature measurements through the transparent upper wall. After the epitaxial deposition process, the epitaxially processed wafer is removed from the chamber body, and a chamber cleaning process is performed to clean (or etch) deposits from the upper wall and other components within the chamber body (e.g., the susceptor) from the preceding epitaxial deposition process. The chamber cleaning process involves heating the chamber body (and walls and components within the chamber) to a suitable temperature and introducing a chamber cleaning gas (e.g., hydrogen chloride) into the chamber body.

The desired temperature of the upper wall of the chamber body for the epitaxial deposition process is different than the desired temperature during the chamber cleaning process. More specifically, during the epitaxial deposition process, a lower temperature of the upper wall is desired to prevent deposits from forming on the upper wall. However, during the chamber cleaning process, a higher temperature of the upper wall is desired to allow etching of the deposited films formed on the upper wall. Thus, the temperature of the upper wall should be dynamically controlled based, at least in part, on a particular process being performed in the reactor. In conventional reactors, cooling fluid (e.g., air) is supplied from a blower which directs the cooling fluid to both an upper module located above the upper wall and a lower module located below the lower wall of the chamber body to regulate temperature of the walls during processing. Typically, the total cooling fluid flow supply rate is controlled based on the upper wall temperature and can be adjusted to provide, for example, more cooling fluid flow to the modules during an epitaxial deposition process step and less cooling fluid flow to the modules during a chamber cleaning process step. However, simply adjusting the total cooling fluid flow supply rate does not provide sufficient control to maintain the upper wall at a stable temperature during each of the discrete process steps. In addition, because deposited films are more likely to form on the exposed upper wall than on the protected lower wall during the epitaxial deposition process, different cooling conditions may be desired in the upper and lower modules during processing (e.g., during a chamber cleaning step). However, adjusting the total cooling fluid flow supplied to the modules does not adequately account for these different cooling conditions.

Accordingly, there exists a need for a reactor cooling control system that allows more dynamic control of cooling fluid flow supplied to the semiconductor wafer reactor to meet desired cooling conditions for each of the upper and lower walls during processing.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect is directed to an epitaxial reactor system for semiconductor wafer processing. The system includes a reactor that includes a reaction chamber having an upper wall and a lower wall, an upper module positioned above the upper wall, and a lower module positioned below the lower wall. The system also includes a cooling circuit that includes a blower to circulate fluid within the upper module and the lower module and a damper selectably positioned to control an amount of fluid flow provided to each of the upper module and the lower module. The damper is coupled to a damper actuator that adjusts a position of the damper. The system further includes a controller configured to: receive epitaxial process information associated with the reactor, generate a blower output and a damper position output based on the epitaxial process information, transmit the blower output to the blower, and transmit the damper position output to the damper actuator.

Another aspect is directed to a cooling system for a semiconductor wafer reactor that includes a cooling circuit including a blower to circulate a cooling fluid within an upper module and a lower module of the reactor and a damper selectably positioned to control an amount of fluid flow provided to each of the upper module and the lower module. The damper is coupled to a damper actuator that adjusts a position of the damper. The system further includes a controller configured to receive epitaxial process information that indicates a specific process step being performed in the reactor, generate a blower output and a damper position output based on the epitaxial process information, transmit the blower output to the blower, and transmit the damper position output to the damper actuator.

A further aspect is directed to a method for cooling a semiconductor wafer reactor. The method includes providing a blower to supply inlet streams of cooling fluid to each of an upper module and a lower module of the reactor. The method also includes providing a damper to control an amount of fluid flow in the inlet streams. The method further includes receiving, by a controller, epitaxial process information associated with the reactor. The method also includes generating a blower output and a damper position output based on the epitaxial process information, transmitting, to the blower, the blower output, and transmitting, to a damper actuator coupled to the damper, the damper position output.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic of an example semiconductor wafer reactor system with dynamic cooling fluid flow control in accordance with the present disclosure.

FIG. 2 is a schematic of cooling fluid supply ducts coupled to a reactor and actuated damper included in the system of FIG. 1.

FIG. 3 is an isolated view of the cooling fluid supply ducts and actuated damper shown in FIG. 2.

FIG. 4 is a diagram of an example control loop for controlling cooling fluid flow supplied to the semiconductor wafer reactor system of FIG. 1.

FIG. 5 is an example process flow for controlling cooling fluid flow conditions during a wafering process step.

FIG. 6 is an example process flow for controlling cooling fluid flow conditions during a chamber cleaning step.

FIG. 7 is a schematic of another example semiconductor wafer reactor system with dynamic cooling fluid flow control in accordance with the present disclosure.

FIG. 8 is an example communication scheme between a reactor, a controller, and a blower inverter used in the semiconductor wafer reactor system of FIG. 7.

FIG. 9 is a schematic of an additional cooling loop used with a semiconductor wafer reactor system according to the present disclosure.

FIGS. 10a-10f show graphs of quartz upper wall temperature profiles during a wafering process step and a chamber cleaning step of an epitaxial process.

FIG. 11 shows boxplots of normalized quartz upper wall temperatures from multiple reactors during a wafering process step and a chamber cleaning step of an epitaxial process.

FIG. 12 shows scatterplots of normalized quartz upper wall temperatures from multiple reactors during a wafering process step of an epitaxial process.

FIG. 13 shows scatterplots of normalized quartz upper wall temperatures from multiple reactors during a chamber cleaning step of an epitaxial process.

Corresponding reference characters indicate corresponding parts throughout the drawings.

### DETAILED DESCRIPTION

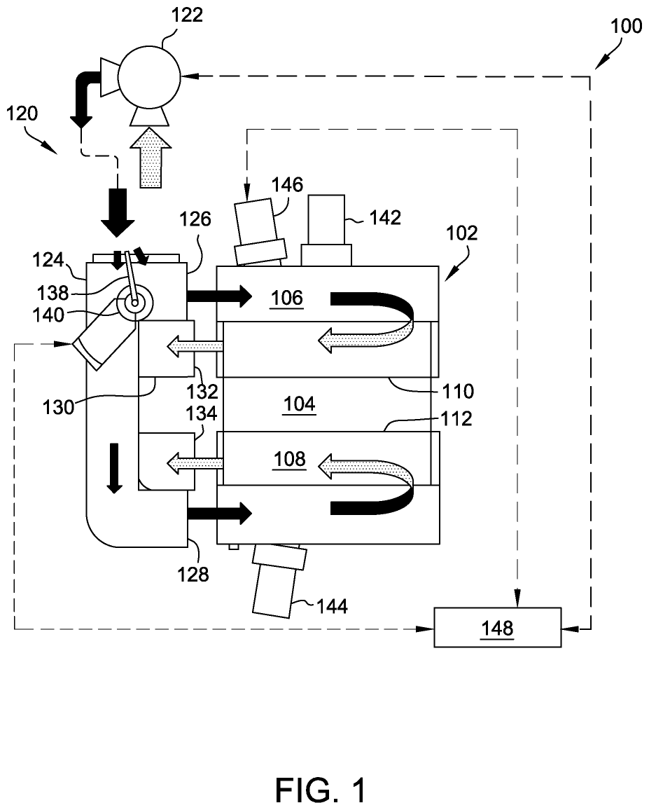

FIG. 1 shows an example semiconductor wafer reactor system 100 in accordance with the present disclosure. System 100 includes a reactor 102, cooling circuit 120, and controller 148. Reactor 102 includes a reaction chamber 104, an upper module 106, and a lower module 108. The illustrated reactor 102 is a single wafer reactor; however, the systems and methods disclosed herein are suitable for use in other reactor designs including, for example, multiple wafer reactors. A gas manifold (not shown) is used to direct process gas into chamber 104, in which the process gas contacts a semiconductor wafer (not shown). The semiconductor wafer is supported within the interior of chamber 104 by a susceptor (not shown). The susceptor is suitably constructed of opaque graphite coated with silicon carbide, though other materials are contemplated.

Example reactors suitable for use with the present disclosure include for example, those disclosed in U.S. Pat. No. 6,083,323 entitled “Method For Controlling The Temperature Of The Walls Of A Reaction Chamber During Processing,” and U.S. Pub. Pat. App. No. 2016/0282886 entitled “Upper Dome Temperature Closed Loop Control,” the disclosures of which are hereby incorporated by reference in their entirety.

The reactor 102 is suitably used to process a wafer in a semiconductor wafering process step. The term “wafering process step,” as used herein, includes without limitation, cleaning (or etching) the wafer, baking (or annealing) the wafer, and depositing any type of material on the wafer performed by a chemical vapor deposition (CVD) process, such as epitaxial CVD or polycrystalline CVD. After the wafering process, or after multiple wafering processes, a chamber cleaning step is performed to etch deposits formed within chamber 104 of reactor 102. The terms “processing” and “epitaxial process,” as used herein, include both a wafering processing step (or an epitaxial deposition process step) and a chamber cleaning step. However, reference herein to “processing” and an “epitaxial process” is not intended to be limited to a process that only includes a single wafering process step and a single chamber cleaning step. In some examples, a chamber cleaning step is performed after two or more wafering process steps, for example, after five wafering process steps. In other words, multiple wafers may be processed in reactor 102 before a chamber cleaning step is performed.

The wafering process step is performed by introducing a process gas recipe of one or more process gases (e.g., silane or chlorinated silane) into chamber 104, which contacts a front surface of the wafer. The wafer is also heated to a suitable temperature so that an epitaxial layer is deposited on the front surface of the wafer. The temperature to which the wafer is heated during the wafering process step is dependent on the process gas recipe, determined by the specific epitaxial layer to be deposited on the wafer. Additionally, the temperature to which the wafer is heated during the wafering process is not necessarily constant, but may change throughout the wafering process step. For example, the wafering process step may also include “baking” (or annealing) the wafer for surface conditioning and to control a bulk oxygen precipitation of the wafer immediately before deposition. The baking portion of the wafering process step involves heating the wafer to a higher temperature than the temperature required during deposition. The wafer temperature is then brought within the required range for deposition after baking.

The chamber cleaning step is performed by introducing a cleaning gas recipe of one or more cleaning gases (e.g., hydrogen chloride) into chamber 104, which contacts components of chamber 104 that are exposed to the process gas recipe introduced during the wafering process step (e.g., upper wall 110 of chamber 104 discussed in more detail below). The exposed components are also heated to a suitable temperature so that deposits on the exposed components can be etched during the chamber cleaning step. To ensure a total amount of deposits are etched, the conditions of the chamber cleaning step may be adjusted based on the number of wafering processes performed before the chamber cleaning step is performed. This is because the amount of deposits on the exposed components within chamber 104 varies depending on the number of wafering process steps run without an intermediate chamber cleaning step. For example, in cases where only one wafering process step is performed before the chamber cleaning step, the amount of deposits formed on the exposed components may be less than the amount formed in cases where two or more wafering process steps are performed before the chamber cleaning step. Adjustments to the conditions of the chamber cleaning step may include adjusting the duration, the cleaning gas recipe (or amount of flow of cleaning gases introduced), and/or the temperature of the chamber cleaning step.

Heat is supplied to chamber 104 using heating elements (not shown) such as, for example, high intensity lamps, resistance heaters and/or inductive heaters. The heating elements are suitably located in an interior of upper module 106 and/or in an interior of lower module 108. The interior of chamber 104 is isolated from the interior of upper module 106 and lower module 108 by upper wall 110 and lower wall 112, respectively. The upper wall 110 and lower wall 112 are typically made of a transparent material to allow radiant heating light to pass into the reaction chamber 104 and onto the wafer (and/or susceptor supporting the wafer). The upper wall 110 and lower wall 112 may be constructed of transparent quartz. Quartz is generally transparent to infrared and visible light and is chemically stable under the reaction conditions of the deposition reaction.

System 100 also includes temperature sensor(s) which measure temperature within reactor 102 during processing. The temperature sensor(s) are suitably located outside chamber 104 due to the high temperatures reached during the process. The temperature sensors may be, for example, optical pyrometers to obtain non-contact high temperature measurements.

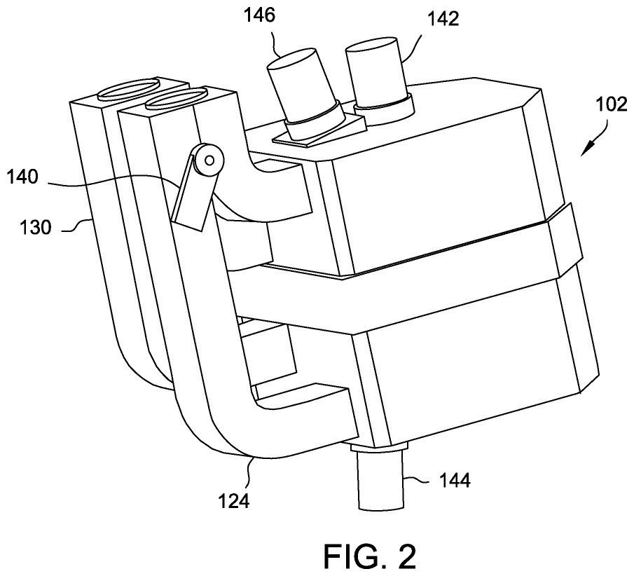

As shown in FIGS. 1 and 2, in the illustrated embodiment, three pyrometers are coupled to reactor 102. A substrate pyrometer 142 is used to measure a temperature of a front surface of the wafer (not shown) positioned in the interior of chamber 104 and exposed to process gases. A susceptor pyrometer 144 is used to measure a temperature of a back surface of the susceptor (not shown) opposite the surface of the susceptor that supports the wafer in the interior of chamber 104. An upper wall pyrometer 146 is used to measure a temperature of the upper wall 110 of reactor 102. In the illustrated embodiment, substrate pyrometer 142 and upper wall pyrometer 146 are positioned on an outer edge at the top of reactor 102, and susceptor pyrometer 144 is positioned on an outer edge at the bottom of reactor 102. However, other configurations of pyrometers 142, 144, 146 may be used to allow each pyrometer to function as described herein.

As shown in FIG. 1, upper wall pyrometer 146 is connected to controller 148 and transmits signals representing a temperature measurement of upper wall 110 to controller 148. One example of an optical pyrometer suitable for use as upper wall pyrometer 146 is an Ircon® Modline® 4 supplied by Ircon, Inc., which is capable of detecting a temperature within the range of 100-800° C. and a wavelength within the range of 1.6-6 μm. The signals may be analog signals, for example, 4-20 mA analog signals. Other temperature measurements may be transmitted to controller 148 in addition, or alternative, to the signal from upper wall pyrometer 146. For example, controller 148 may be connected to, and receive temperature measurements of the wafer surface from, substrate pyrometer 142, and/or may be connected to, and receive temperature measurements of the back susceptor surface from, susceptor pyrometer 144.

During processing, although upper wall 110 and lower wall 112 are suitably transparent, the heat supplied to chamber 104 causes a temperature of the upper and lower walls 110, 112 to increase. When heated during a wafering process step, exposure of the walls 110, 112 to the process gases introduced during the wafering process step results in deposit films forming thereon. Reactor 102 may be configured to protect lower wall 112 from exposure, but upper wall 110 remains exposed due to its proximity to the front surface of the wafer. As a result, deposit films may form on the exposed surface on upper wall 110 in chamber 104 when heated during the wafering process step. The deposit films deteriorate the transparency of the upper wall 110, thereby negatively influencing the temperature measurements obtained by substrate pyrometer 142 which are used to control the temperature of the wafer surface during deposition. The transparency of the upper wall 110 can be maintained by controlling the temperature of the upper wall 110 to prevent deposit films from forming thereon during the wafering process step (i.e., by reducing the temperature of upper wall 110 when process gases are introduced during the wafering process step) and to facilitate etching of deposits during the chamber cleaning step (i.e., by increasing the temperature of upper wall 110 when cleaning gases are introduced during the cleaning process step).

System 100 includes a cooling circuit 120 to regulate the temperature of upper and lower walls 110, 112 during processing. Cooling circuit 120 includes blower 122 that supplies a cooling fluid (e.g., air) to upper module 106 and lower module 108 of reactor 102. The cooling fluid circulates through upper and lower modules 106, 108 and contacts upper and lower walls 110, 112, respectively, thereby mitigating the temperature increase of the upper and lower walls 110, 112 caused by the heating elements. The cooling fluid has the additional effect of mitigating an increase of temperature of other components located within, or positioned on, upper and lower modules 106, 108, such as the heating elements described herein.

Cooling circuit 120 also includes ducts 124, 130 (shown in FIGS. 1-3) through which cooling fluid flows between blower 122 and upper and lower modules 106, 108. Duct 124 has a first outlet 126 in fluid communication with upper module 106 and a second outlet 128 in fluid communication with lower module 108. Duct 130 has a first inlet 132 in fluid communication with upper module 106 and a second inlet 134 in fluid communication with lower module 108. A discharge-side of blower 122 is in fluid communication with duct 124 and supplies the cooling fluid to the upper and lower modules 106, 108 through duct 124. A suction-side of blower 122 is in fluid communication with duct 130. The cooling fluid circulates through each of the upper and lower module 106, 108 and is drawn back to blower 122 through duct 130.

The amount of cooling fluid supplied by blower 122 to duct 124 is controlled by controller 148 which is connected to blower 122. Controller 148 is configured to transmit a signal to blower 122 which causes blower 122 to adjust the output rate of cooling fluid to duct 124. For example, blower 122 may be a variable speed blower with an external or built-in inverter. Controller 148 may transmit a signal to the inverter of variable speed blower 122 which causes variable speed blower 122 to adjust its speed and thus, the total rate of the cooling fluid supplied to upper and lower modules 106, 108, collectively. The inverter of blower 122 is also configured to transmit a feedback signal to controller 148 which indicates the output rate of cooling fluid supplied by blower 122. For example, the inverter of variable speed blower 122 may transmit a signal to controller 148 that indicates the speed of blower 122. The signals exchanged between the inverter of blower 122 and controller 148 may be analog signals, for example, 0-10 Volts analog signals, or may be digital signals. As discussed in more detail herein, controller 148 generates the signal transmitted to blower 122 based on one or more processing conditions of reactor 102.

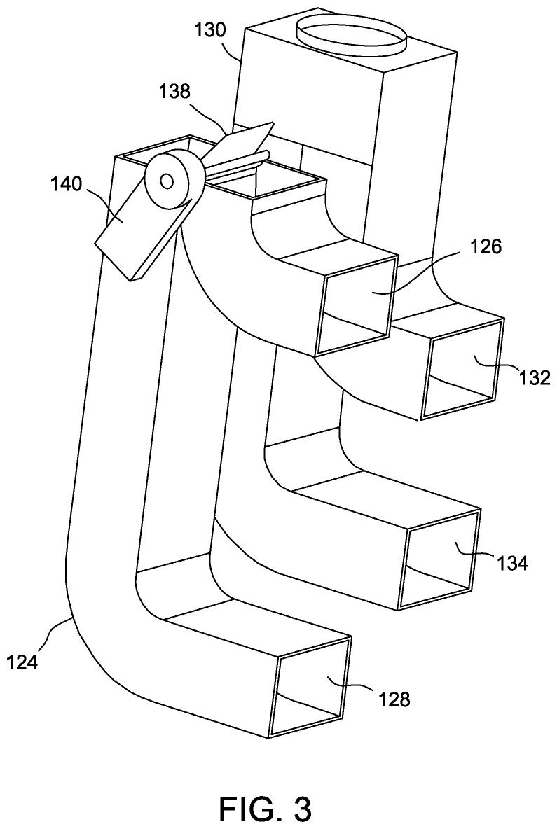

As shown in FIGS. 1-3, and particularly in FIG. 3, cooling circuit 120 also includes a damper 138 located in duct 124 that regulates an amount of cooling fluid supplied to each outlet 126, 128 and thus, to the upper and lower modules 106, 108. Damper 138 may suitably be located in duct 124 at a point where the fluid supplied to duct 124 is separated into two portions, one of which is supplied to outlet 126 (and therefore upper module 106) and the other of which is supplied to outlet 128 (and therefore lower module 108). At this juncture, damper 138 can be selectably positioned so as to control the amount of cooling fluid in each portion. As discussed above, the transparency of upper wall 110, the surface of which is exposed in chamber 104 to process gases introduced during a wafering process step, can be maintained by controlling the temperature of the upper wall 110 during the wafering process step and the chamber cleaning step. Controller 148 can adjust the total output rate of cooling fluid by controlling blower 122, but the configuration of cooling circuit 120 is such that blower 122 supplies a balanced amount of cooling fluid to the upper and lower modules 106, 108. Because the lower wall 112 may be protected (i.e., not exposed or significantly less exposed to process gases), there is less potential that deposit films will form on a surface of lower wall 112. Thus, it is not always desirable to supply a balanced amount of cooling fluid to upper and lower modules 106, 108 (such as, for example, during a chamber cleaning step). In this regard, the selective positioning of damper 138 allows more control of the cooling conditions desired in each of the upper module 106 and lower module 108 during processing. For example, if damper 138 is positioned to increase the amount of cooling fluid supplied to outlet 126, then the amount of cooling fluid supplied to outlet 128 decreases, and if damper 138 is positioned to decrease the amount of cooling fluid supplied to outlet 126, then the amount of cooling fluid supplied to outlet 128 increases.

Damper 138 is coupled to actuator 140 which is configured to adjust the position of damper 138. Suitable actuators used as actuator 140 include, for example, damper actuators supplied by BELIMO®. Actuator 140 is equipped with damper position feedback and is connected to controller 148. Actuator 140 can thereby transmit feedback signals related to the position of damper 138 to controller 148. Controller 148 is configured to transmit a signal to actuator 140 which causes actuator 140 to adjust the position of damper 138. Actuator 140 thus facilitates remote control of a position of damper 138 without requiring equipment stop to manually adjust a position of damper 138. The signals exchanged between actuator 140 and controller 148 may be analog signals, for example, 0-10 Volts analog signals. As discussed in more detail herein, controller 148 generates the signal transmitted to actuator 140 based on one or more processing conditions of reactor 102.

As discussed above, controller 148 is connected to upper wall pyrometer 146, and is connected to blower 122 and actuator 140. Controller 148 is configured to adjust the supply of cooling fluid from cooling circuit 120 to each of upper and lower modules 106, 108 by dynamically controlling both blower 122 and actuator 140 coupled to damper 138. Controller 148 can generally include any suitable computer and/or other processing unit, including any suitable combination of computers, processing units and/or the like that may be connected to one another (e.g., controller 148 can form all or part of a controller network). Thus, controller 148 can include one or more processor(s) and associated memory device(s) configured to perform a variety of computer-implemented functions (e.g., performing the methods, steps, calculations and/or the like disclosed herein). As used herein, the term “processor” refers not only to integrated circuits referred to in the art as being included in a computer, but also refers to a controller, a microcontroller, a microcomputer, a programmable logic controller (PLC), an application specific integrated circuit (ASIC), a digital signal processor (DSP), a field programmable gate array (FPGA), and other programmable circuits. Additionally, the memory device(s) of controller 148 may generally include memory element(s) including, but not limited to, non-transitory computer readable medium (e.g., random access memory (RAM)), computer readable non-volatile medium (e.g., a flash memory), a floppy disk, a compact disc-read only memory (CD-ROM), a magneto-optical disk (MOD), a digital versatile disc (DVD) and/or other suitable memory elements. Such memory device(s) can generally be configured to store suitable computer-readable instructions that, when implemented by the processor(s), configure the controller 148 to perform various functions including, but not limited to, controlling functions of blower 122 and actuator 140 as described herein.

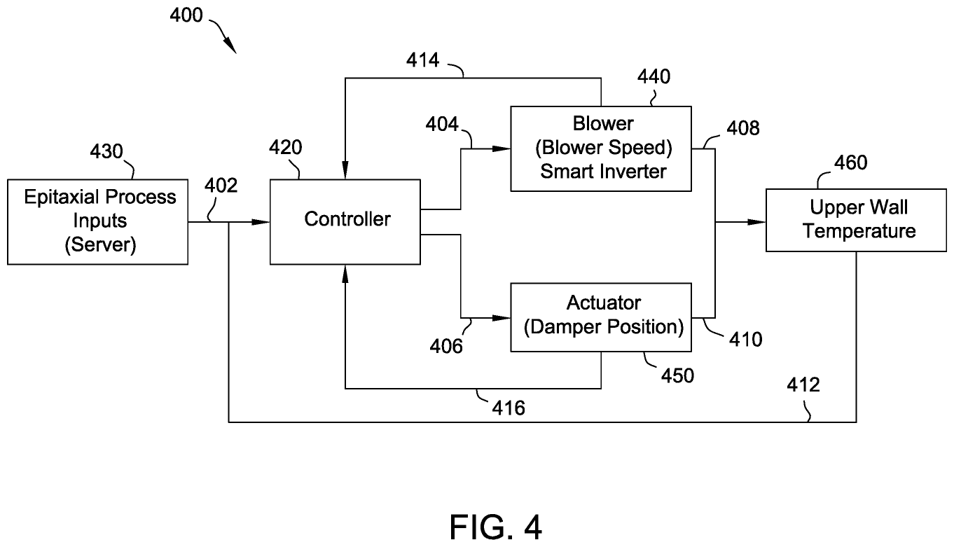

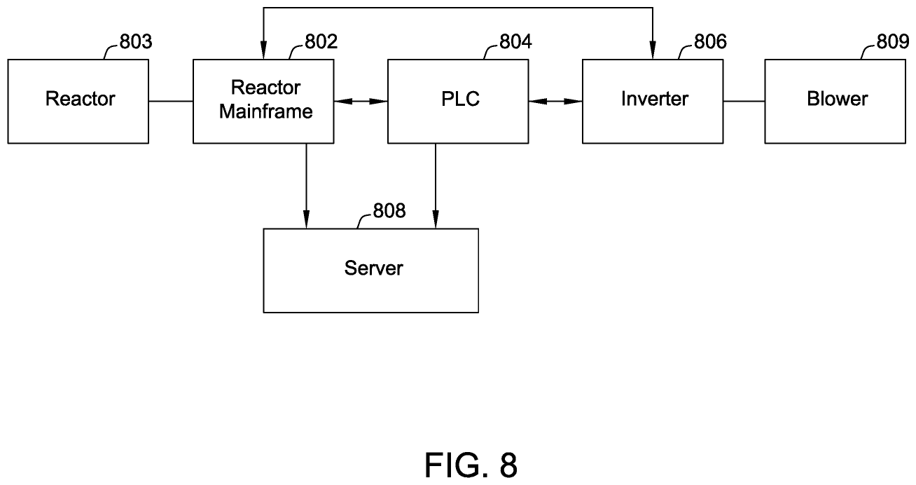

FIG. 4 shows an example control loop 400 used by controller 148 (schematically represented in FIG. 4 as controller 420) to control the supply of cooling fluid flow to upper and lower modules 106, 108 during processing. At line 402, controller 420 receives process parameter inputs 430 which provide information to controller 420 which allows controller 420 to generate control outputs. Controller 420 is connected to a host server (for example, host server 808 shown in FIG. 8) which transmits process parameter inputs 430 to controller 420. The host server is also connected to a processing unit of reactor 102 (for example, reactor mainframe 802 shown in FIG. 2), from which it receives the information transmitted as process parameter inputs 430 to controller 420. Controller 420 and the processing unit of reactor 102 each communicate with the host server via a communication protocol, for example, a SECS/GEM (SEMI Equipment Communications Standard/Generic Equipment Model) standard communication interface protocol or an OPC standard protocol.

Inputs 430 include processing information associated with a specific epitaxial process step. For example, controller 420 receives inputs 430 that indicate whether a wafering process step or a chamber cleaning step is being performed by reactor 102, or whether reactor 102 is in an idle or “cool down” mode. Controller 420 may also receive inputs 430 that indicate specific parameters of the wafering process step or the chamber cleaning step, such as the process gas recipe used during the wafering process step or cleaning gas recipe used during the chamber cleaning step. Controller 420 also receives a target temperature of upper wall 110 in inputs 430, or determines a target temperature of upper wall 110 based on inputs 430.

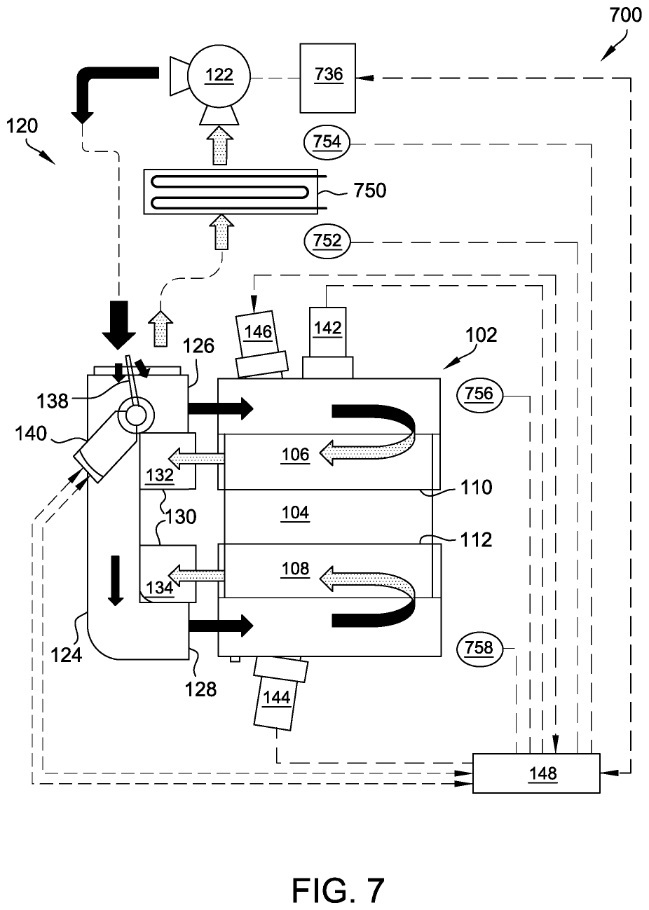

Controller 420 generates a blower output 404 and a damper position output 406 based on inputs 430. Outputs 404, 406 are generated to achieve target conditions of the cooling fluid flow supplied from cooling circuit 120 to upper module 106 and lower module 108. Target cooling fluid flow conditions include a target total output rate of cooling fluid supplied from blower 122, a target amount of cooling fluid supplied to upper module 106, and a target amount of cooling fluid supplied to lower module 108. The target cooling fluid flow conditions may be pre-determined or may be determined in real-time by controller 420. Pre-determined target cooling fluid flow conditions may be based on user experience or historical processing data of reactor 102, or may otherwise be desired cooling fluid flow conditions for the specific epitaxial process step associated with the processing information received with inputs 430. Real-time determinations of target cooling fluid flow conditions made by controller 420 may be based on measured processing parameters of reactor 102, such as, for example, temperature measurements received by controller 420 from upper wall pyrometer 146, and, optionally, pressure measurements of cooling fluid flow within the upper and lower modules 106, 108 received by controller 420 from pressure sensors (such as pressure sensors 756, 758 shown in FIG. 7).

Outputs 404, 406 are generated by controller 420 and transmitted to blower 122 (schematically represented in FIG. 4 as blower 440) and actuator 140 (schematically represented in FIG. 4 as actuator 450), respectively. Output 404 is transmitted to blower 440 to cause blower 440 to adjust the total output rate of cooling fluid supplied by blower 440 (schematically represented in FIG. 4 by line 408). Output 406 is transmitted to actuator 450 to adjust the position of damper 138 which adjusts the amount of cooling fluid flow to each of the upper and lower modules 106, 108 (schematically represented in FIG. 4 by line 410). The outputs 404, 406 thereby allow controller 420 to control both the total rate of cooling fluid supplied to upper and lower modules 106, 108, collectively, as well as the amount of cooling fluid supplied individually to upper and lower modules 106, 108.

Controller 420 updates outputs 404, 406 when new inputs 430 are received to dynamically control the cooling fluid flow conditions in each of upper and lower modules 106, 108 throughout processing. This allows controller 420 to adjust the cooling fluid flow conditions to desired conditions that are constantly changing during processing. For example, during a wafering process step, balanced cooling fluid flow conditions in upper and lower modules 106, 108 may be desired. Controller 420 receives inputs 430 indicating a wafering process step is being performed and generates output 404 to cause blower 440 to supply an appropriate output rate of cooling fluid and generates output 406 to cause actuator 450 to position damper 138 to direct balanced amounts of cooling fluid to the upper and lower modules 106, 108. Processing continues with a chamber cleaning step, during which decreased cooling fluid flow may be desired in upper module 106 to allow the upper wall 110 to increase in temperature, while increased cooling fluid flow may still be desired in lower module 108. Controller 420 receives new inputs 430 indicating a chamber cleaning step is being performed and generates an updated output 406 to cause actuator 450 to position damper 138 to direct an increased amount of cooling fluid to lower module 108 (which decreases the amount of cooling fluid supplied to upper module 106). Controller 420 also generates an updated blower output 404 based on new inputs 430 which also compensates for the reduced amount of cooling fluid supplied to upper module. That is, to achieve the same cooling conditions in upper module 106 that would be achieved if a balanced amount of cooling fluid were supplied to the upper and lower modules 106, 108, the appropriate output rate of cooling fluid supplied by blower 122 should be greater than it would have been under the balanced flow conditions. This provides more cooling fluid flow to the lower module 108, and causes blower 122 to operate above a minimum output level which allows better feedback control.

In the example control loop 400, the temperature of upper wall 110 (schematically represented in FIG. 4 as upper wall temperature 460) is a controlled parameter used by loop 400 during processing. As discussed above, upper wall temperature 460 is measured by upper wall pyrometer 146. Controller 420 is connected to upper wall pyrometer 146, which transmits upper wall temperature 460 to controller 420 at line 412. In this example, controller 420 also receives from inputs 430 (or determines based on inputs 430) a target temperature of the upper wall 110 during the specific epitaxial process step.

During a wafering process step or a chamber cleaning step, the target temperature of upper wall 110 typically remains constant when process gases or cleaning gases are introduced into the chamber 104. The controller 420 uses feedback control, such as proportional-integral-derivative (PID) control, to maintain a stable upper wall temperature 460 at or near the target temperature during the processing step. For example, controller 420 uses PID control to continuously update blower output 404 based on a difference between upper wall temperature 460 and the target temperature. To facilitate feedback control, controller 420 receives at line 414 a feedback signal from blower 440. In addition, controller 420 receives at line 416 a feedback signal from actuator 450. The position of damper 138 affects the cooling fluid flow conditions in upper module 106 (and thus the change of upper wall temperature 460). Controller 420 therefore uses feedback signals from each of blower 440, actuator 450, and upper wall temperature 460 in generating the updated blower output 404 using feedback control. A range of updated outputs 404 generated during feedback control of a specific processing step may be known and used to set the position of damper 138 during the specific processing step to increase/extend the blower control range.

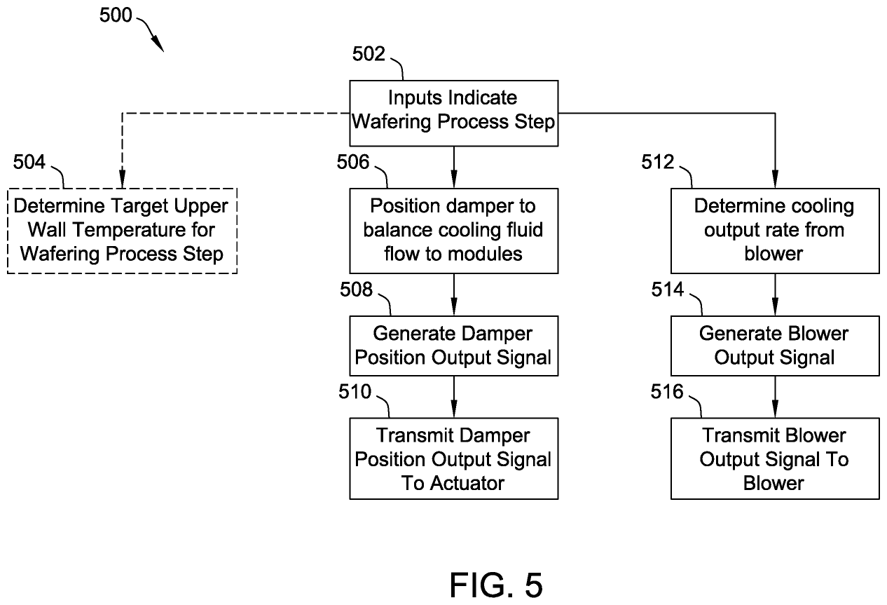

FIG. 5 shows an example process flow 500 for controlling cooling fluid flow conditions during a wafering process step. At step 502, controller 420 receives epitaxial process information via inputs 430 that indicates a wafering process step is being performed in reactor 102. The epitaxial process information may also include a specific process gas recipe involved in the wafering process step.

At step 504, in the example process flow 500, the controller 420 determines a target upper wall temperature at step 504 for the wafering process step. Controller 420 may make this determination by accessing data in stored memory which associates a target temperature with the wafering process step (and, optionally, with specific process gas recipe if this information is also received). In other examples, step 504 may not be executed if a target upper wall temperature is received as part of the wafering process step information at step 502.

Based on the information received at step 502 that indicates a wafering process step is being performed in reactor 102, controller 420 at step 506 determines an appropriate position of damper 138. In this example, controller 420 determines that damper 138 should be positioned so that balanced amounts of cooling fluid flow are supplied to upper and lower modules 106, 108. In other examples, controller 420 may determine that damper 138 should be positioned so that different amounts of cooling fluid flow are supplied to upper and lower modules 106, 108. The appropriate position of damper 138 may be based on user experience or historical data of reactor 102 associated with the wafering process step (and, optionally, with the specific process gas recipe if this information is also received). Controller 420 generates a damper position output signal at step 508 based on this determination. At step 510, controller 420 transmits the generated damper position output signal that causes actuator 140 to position damper 138 to the appropriate position. In some instances, steps 508 and 510 may not be executed if controller 420 determines, using feedback information received from actuator 140, that damper 138 is already positioned in the appropriate position determined at step 506.

Also based on the information received at step 502 indicating a wafering process step is being performed in reactor 102, controller 420 at step 512 determines an appropriate output rate of cooling fluid flow supplied by blower 122. The appropriate output rate is determined based on the specific target cooling conditions during the wafering process step which may be based on user experience or historical data of reactor 102 associated with the wafering process step (and, optionally, with the specific process gas recipe if this information is also received). Controller 420 generates a blower output signal at step 514 based on this determination. At step 516, controller 420 transmits the generated blower output signal that causes actuator 140 to adjust the output rate of cooling fluid flow supplied by blower 122 to the appropriate rate.

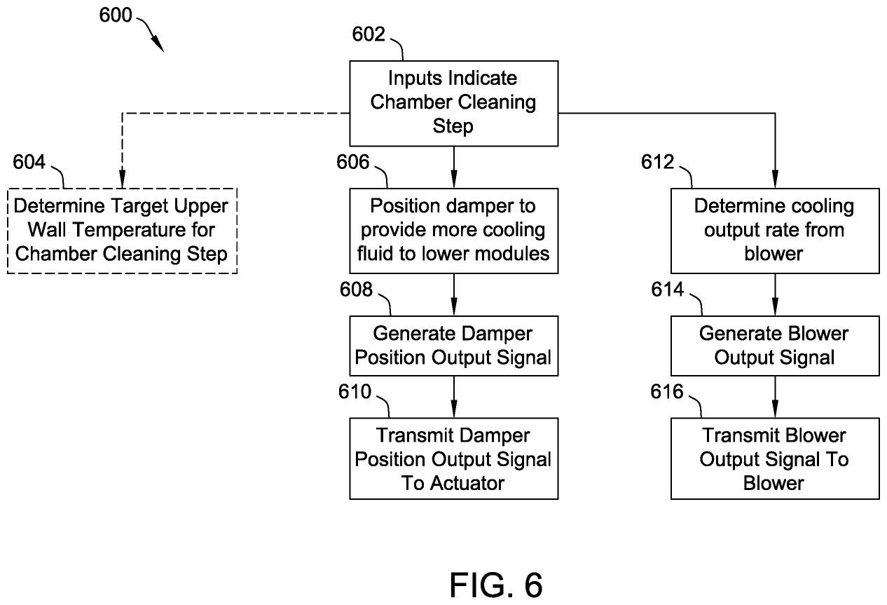

FIG. 6 shows an example process flow 600 for controlling cooling fluid flow conditions during a chamber cleaning step. At step 602, controller 420 receives epitaxial process information via inputs 430 that indicates a chamber cleaning step is being performed in reactor 102. The chamber cleaning step may be performed after one or more wafering processes according to process 500 have been performed. The epitaxial process information may also include a specific cleaning gas recipe involved in the chamber cleaning step.

At step 604, in the example process flow 600, the controller 420 determines a target upper wall temperature at step 604 for the chamber cleaning step. Controller 420 may make this determination by accessing data in stored memory which associates a target temperature with the chamber cleaning step (and, optionally, with specific cleaning gas recipe if this information is also received). In other examples, step 604 may not be executed if a target upper wall temperature is received as part of the chamber cleaning step information at step 602.

Based on the information received at step 602 that indicates a chamber cleaning step is being performed in reactor 102, controller 420 at step 606 determines an appropriate position of damper 138. In this example, controller 420 determines that damper 138 should be positioned so that a higher amount of cooling fluid flow is supplied to lower module 108 (and thus, a lower amount is supplied to upper module 106). In other examples, controller 420 may determine that damper 138 should be positioned so that different amounts of cooling fluid flow are supplied to upper and lower modules 106, 108. The appropriate position of damper 138 during the chamber cleaning step indicated at step 602 may be based on user experience or historical data of reactor 102 associated with the chamber cleaning step (and, optionally, with the specific cleaning gas recipe if this information is also received). Controller 420 generates a damper position output signal at step 608 based on this determination. At step 610, controller 420 transmits the generated damper position output signal that causes actuator 140 to position damper 138 to the appropriate position. In some instances, steps 608 and 610 may not be executed if controller 420 determines, using feedback information received from actuator 140, that damper 138 is already positioned in the appropriate position determined at step 606.

Also based on the information received at step 602 that indicates a chamber cleaning step is being performed in reactor 102, controller 420 at step 612 determines an appropriate output rate of cooling fluid flow supplied by blower 122. The appropriate output rate is determined based on the specific target cooling conditions during the chamber cleaning step which may be based on user experience or historical data of reactor 102 associated with the chamber cleaning step (and, optionally, with the specific cleaning gas recipe if this information is also received). Controller 420 generates a blower output signal at step 614 based on this determination. At step 616, controller 420 transmits the generated blower output signal that causes actuator 140 to adjust the output rate of cooling fluid flow supplied by blower 122 to the appropriate rate.

The example process flows 500, 600 taken together represent an example process flow for controlling cooling fluid flow conditions during an overall epitaxial process (i.e., a process that includes a wafering process step and a chamber cleaning step). The example process flows 500, 600 demonstrate the capability of controller 420 to dynamically control the cooling fluid flow conditions during an epitaxial process based on the desired cooling conditions during discrete steps of the process. More specifically, controller 420 is configured to dynamically control blower 122 and actuator 140 to adjust the overall output rate of cooling fluid flow as well as the amount of cooling fluid flow supplied to each of the upper module 106 and lower module 108 between a wafering process step and a chamber cleaning step (and optionally, during the wafering process step and chamber cleaning step if desired conditions change during the respective step).

FIG. 7 shows a semiconductor wafer reactor system 700 in accordance with another embodiment. System 700 includes features similar to those described above with respect to FIG. 1, with additional or modified features discussed in more detail below. Reference symbols in FIG. 1 are used for similar features in FIG. 7. Additional details discussed above with respect to the features of system 100 also apply to similar features of system 700 unless expressly stated otherwise.

System 700 includes inverter 736 connected to blower 122 and controller 148. In the example embodiment shown in FIG. 7, blower 122 is a variable speed blower. Inverter 736 is configured to manage the speed of variable speed blower 122 based on a blower speed setpoint received from controller 148.

FIG. 8 shows an example communication scheme for reactor 102, controller 148, and inverter 736 (which are schematically represented in FIG. 8 as reactor 803, PLC 804, and inverter 806). Reactor mainframe 802 is coupled to reactor 803 and includes one or more central processing units (CPUs) (or processors) and associated memory device(s) configured to perform a variety of computer-implemented functions to control operations of reactor 803. The CPU(s) may be a standard computer processor or controller. The memory device(s) of reactor mainframe 802 may generally include memory element(s) including, but not limited to, non-transitory computer readable medium (e.g., random access memory (RAM)), computer readable non-volatile medium (e.g., a flash memory), a floppy disk, a compact disc-read only memory (CD-ROM), a magneto-optical disk (MOD), a digital versatile disc (DVD) and/or other suitable memory elements. Process information associated with reactor 803 may be stored as a software routine in the memory device(s) of reactor mainframe 802. Reactor mainframe 802 is connected to and communicates with host server 808. For example, reactor mainframe 802 may be configured to communicate with host server 808 over a SECS/GEM (SEMI Equipment Communications Standard/Generic Equipment Model) standard communication interface using a SECS transmission protocol. Process data communications such as epitaxial process steps and specific process and cleaning gas recipes may be transmitted from host server 808 to reactor mainframe 802 over the SECS protocol which causes reactor 803 to start or stop the appropriate processing step. Data communications such as reactor equipment status and processing step status may be transmitted from reactor mainframe 802 to host server 808 over the SECS protocol to allow host server 808 to monitor reactor 803 in real-time.

Reactor mainframe 802 is also in communication with PLC 804 and Inverter 806. Reactor mainframe 802 may be configured to transmit epitaxial process information to PLC 804, such as process step information and specific process and cleaning gas recipe information. Reactor mainframe 802 may be configured to transmit a blower start/stop signal to inverter 806 which causes inverter to start/stop blower 122 (schematically represented in FIG. 8 as blower 809). The start/stop signal may be transmitted from reactor mainframe 802 to inverter 806 when reactor mainframe 802 receives a reactor start/stop signal from host server 808 to start/stop reactor 803. In some embodiments, the blower start/stop signal may include a blower speed setpoint, and the blower speed setpoint may be transmitted to both inverter 806 and PLC 804.

PLC 804 is in communication with inverter 806 and configured to control a speed of blower 809 by transmitting a blower speed setpoint signal to inverter 806. As discussed above, PLC 804 may also be equipped with feedback control capability (e.g., PID control capability) to generate updated blower speed setpoint signals. PLC 804 may digitally communicate blower speed setpoint signals to inverter 806. For example, PLC 804 and inverter 806 may communicate via an EtherCAT fieldbus for digital data communication. PLC 804 may suitably be a programmable logic controller with built-in EtherCAT communication, such as an NX1 series controller supplied by OMRON® (e.g., NX102 controller). Inverter 806 is suitably an inverter with built-in EtherCAT communication, such as those supplied by OMRON®. Such inverters suitable for use as inverter 806 may also digitally communicate (e.g., using EtherCAT) feedback signals of motor parameters of blower 809 such as current, power, and voltage.

In this embodiment PLC 804 is also in communication with host server 808. For example, the controllers suitable for use as PLC 804 may also be configured to communicate with host server 808 over a SECS/GEM standard communication interface using a SECS transmission protocol, or in accordance with an OPC standard such as, for example, using an OPC Unified Architecture (UA) standard protocol. Real-time process data communications may be exchanged between host server 808 and PLC 804 over the SECS or OPC UA protocol. More specifically, real-time process information associated with reactor 803 is transmitted from server 808 to PLC 804, and PLC 804 transmits to server 808 feedback information received from one or more additional process components not monitored by reactor mainframe 802. For example, PLC 804 transmits feedback signals received from inverter 806 to server 808 over the SECS or OPC UA protocol. PLC 804 may also be connected to other process components (such as additional temperature and/or pressure sensors) that are not monitored by reactor mainframe 802, and may transmit feedback information from these components to server 808 to improve process monitoring and detection of component faults and operational issues.

Referring back to FIG. 7, system 700 includes heat exchanger 750 located between the outlet of duct 130 and the suction-side of blower 122. Heat exchanger 750 is configured to cool the return cooling fluid (i.e., warmed fluid) that is drawn back to blower 122 from upper and lower modules 106, 108 through duct 130. In this embodiment, a warmed fluid temperature sensor 752 is located at or near inlet of heat exchanger 750, and a cooled fluid (i.e., fluid cooled by heat exchanger 750) temperature sensor 754 is located at or near outlet of heat exchanger 750. Both temperature sensors 752, 754 are connected to controller 148 which receives the measured temperature of the warmed fluid at the inlet and the cooled fluid at the outlet of heat exchanger 750. Controller 148 may make various determinations based on the received measurements from temperature sensors 752, 754. For example, controller 148 may determine a fault or operational issue of system 700 if a difference between the measured temperatures received from temperature sensors 752, 754 is below an acceptable limit. Controller 148 may also determine a fault or operational issue of system 700 if the measured temperature received from cooled fluid temperature sensor 754 is above an acceptable limit. Controller 148 may also generate output signals transmitted to blower 122 and actuator 140, discussed in detail above, based in part on the measurement from cooled fluid temperature sensor 754. In some embodiments, only one of temperature sensors 752, 754 may be used.

System 700 also includes pressure sensors 756, 758 coupled to upper and lower modules 106, 108, respectively. The pressure sensors 756, 758 measure a pressure of cooling fluid flow within the respective upper and lower module 106, 108. In the illustrated embodiment, both pressure sensors 756, 758 are connected to controller 148. Controller 148 may make various determinations based on the received measurements from pressure sensors 756, 758. For example, controller 148 may determine a fault or operational issue of system 700 if the measured pressure received from sensors 756, 758 indicates inadequate flow to upper and lower modules 106, 108 that cannot be reconciled with the current set output rate from blower 122 and/or set position of damper 138. In some embodiments, only one of pressure sensors 756, 758 may be used.

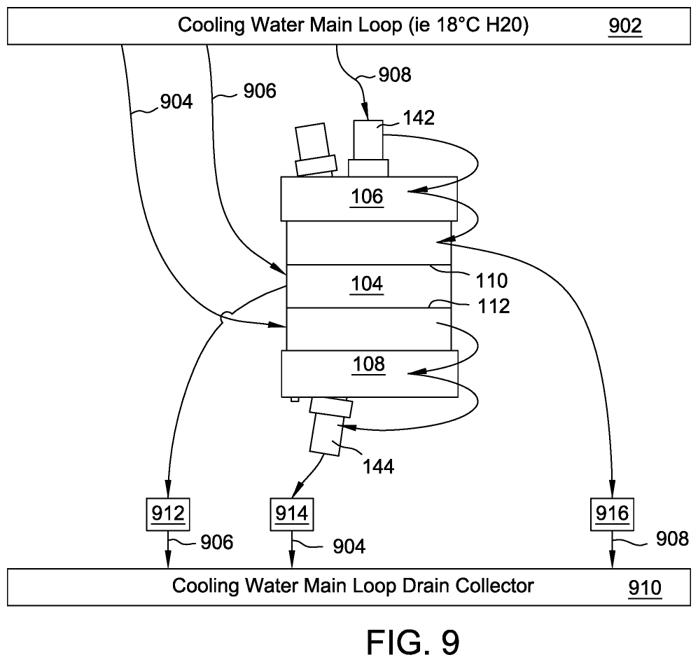

FIG. 9 shows an example cooling loop 900 for use with a semiconductor wafer reactor system (e.g., system 100 shown in FIG. 1, system 700 shown in FIG. 7). Cooling loop 900 provides additional cooling to components of reactor 102 (i.e., in addition to cooling circuit 120). In the illustrated embodiment, cooling loop 900 uses cold water (e.g., having a temperature of about 18° C.) to supply cooling to the components of reactor 102. However, in other embodiments, other cooling liquid may be used.

Cooling loop 900 includes a cooling main loop 902 comprising a cooling liquid (e.g., water as shown in FIG. 9). Cooling liquid is supplied from main loop 902 to each of a lower module cooling loop 904, a chamber cooling loop 906, and an upper module cooling loop 908. The lower module cooling loop 904 supplies cooling liquid to lower module 108 and susceptor pyrometer 144. Cooling liquid in lower module cooling loop 904 may also contact components located in the interior of lower module 108, such as a lower clamp ring and a gold reflector. The chamber cooling loop 906 supplies cooling liquid to reaction chamber 104. The upper module cooling loop 908 supplies cooling liquid to upper module 106 and substrate pyrometer 142. Cooling liquid in upper module cooling loop 908 may also contact components located in the interior of upper module 106, such as an upper clamp ring and a gold reflector. Drain collector loop 910 receives cooling liquid at the outlets of each of the lower module cooling loop 904, the chamber cooling loop 906, and the upper module cooling loop 908.

Cooling loop 900 also includes sensors 912, 914, 916 coupled to each of the lower module cooling loop 904, the chamber cooling loop 906, and the upper module cooling loop 908. Each sensor 912, 914, 916 measures one or more parameters of the cooling fluid in the respective loop 904, 906, 908. For example, the sensors 912, 914, 916 may each be a temperature sensor, a flow sensor (e.g., a volumetric flow sensor or a mass flow sensor), a pressure sensor, or a combination thereof. In this example, sensors 912, 914, 916 are each a combined temperature and flow sensor. The sensors 912, 914, 916 are each suitably positioned on the respective loop downstream from the components that are contacted by the cooling liquid in the respective loop. That is, sensors 912, 914, 916 suitably measure one or more parameters of cooling fluid after contacting the components.

The sensors 912, 914, 916 may each be connected to a controller (i.e., controller 148) which receives the measured parameter(s) of each loop 904, 906, 908 from the respective sensor. The controller may also receive measurement(s) of the same parameter(s) of the cooling fluid in main loop 902. The controller may make determinations by comparing the measured parameter(s) of the cooling fluid in each loop 904, 906, 908 with the measured parameter(s) of the cooling fluid in main loop 902. For example, the controller may detect a fault or operational issue associated with one of loops 904, 906, 908 if a temperature differential, pressure differential, or flow differential is above or below an acceptable value.

### EXAMPLES

The processes of the present disclosure are further illustrated by the following Example. This Example should not be viewed in a limiting sense.

### Example 1: Determining the Effect of Dynamically Controlling Blower Speed and Damper Position on the Temperature Profile of the Upper Wall of an Epitaxial Reaction Chamber

A method of controlling cooling fluid flow conditions in the upper and lower modules of a reaction chamber as described herein was tested to determine the effect on the upper wall temperature profile during an epitaxial process. The reactors used were CENTURA® EPI 200 mm supplied by Applied Materials®. Quartz upper wall temperature profile data was collected from conventional reactors using a standard variable speed blower and from reactors equipped with an actuated damper and a controller configured to control the actuated damper based on a processing step, and to control the variable speed blower using PID control, as described herein.

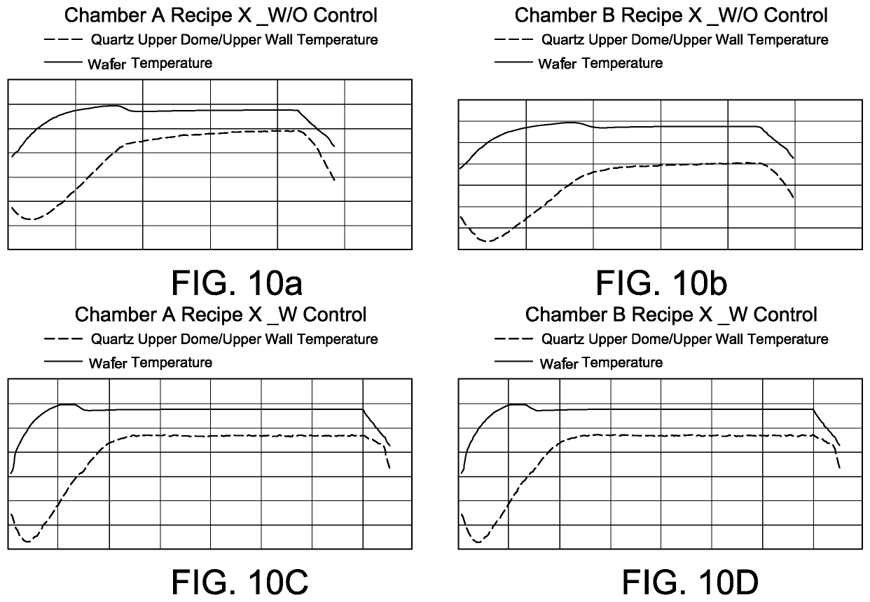

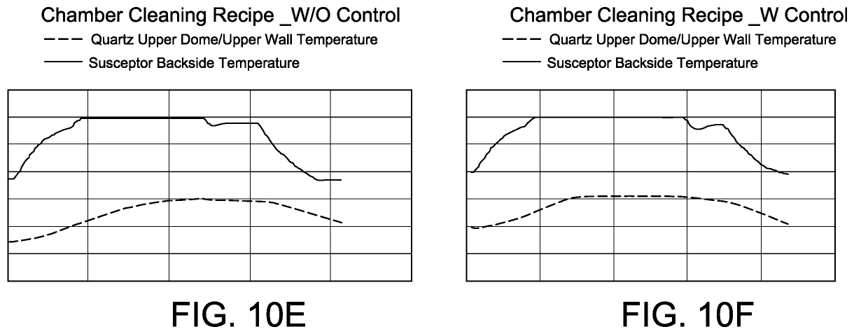

FIGS. 10a-10f show temperature profiles for a quartz upper wall during a wafering process (FIGS. 10a-10d) and a chamber cleaning process (FIGS. 10e-10f). The quartz upper wall temperature profiles demonstrate more stable temperature control in a reactor equipped in accordance with the present disclosure (FIGS. 10c, 10d, and 10f) compared to temperature profiles in a reactor using a standard variable speed blower (FIGS. 10a, 10b, and 10e). Notably, stable temperature control of the quartz upper wall temperature was maintained in FIGS. 10c and 10d during a wafering process that included varying temperature conditions due to initial wafer baking (shown by the initial higher temperature on the wafer temperature profile). The more stable temperature profile during the chamber cleaning step in FIG. 10f versus that of FIG. 10e is also of particular importance, as the quartz upper wall temperature must be maintained at or near the setpoint for a sufficient duration while the cleaning gas is introduced to the chamber to ensure adequate etching of deposits during the chamber cleaning step.

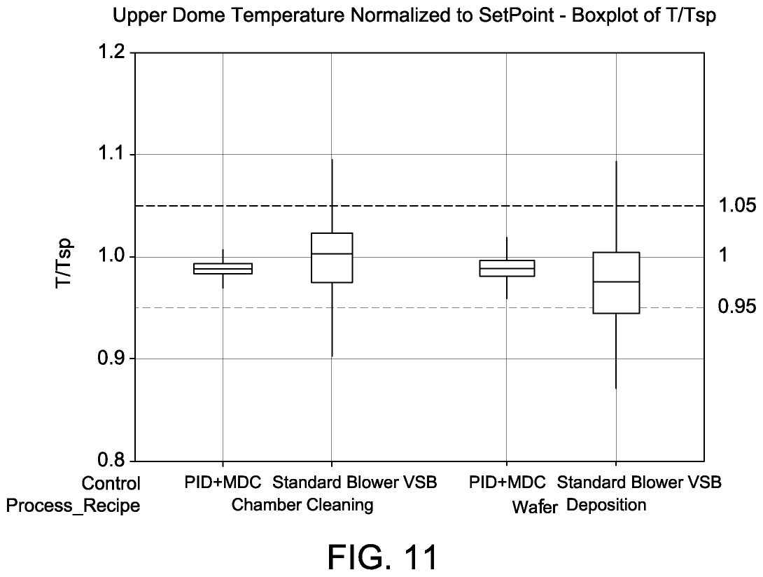

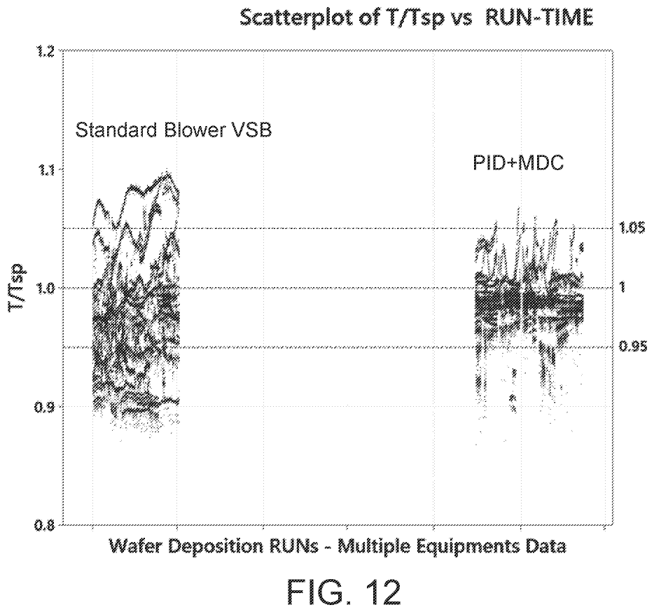

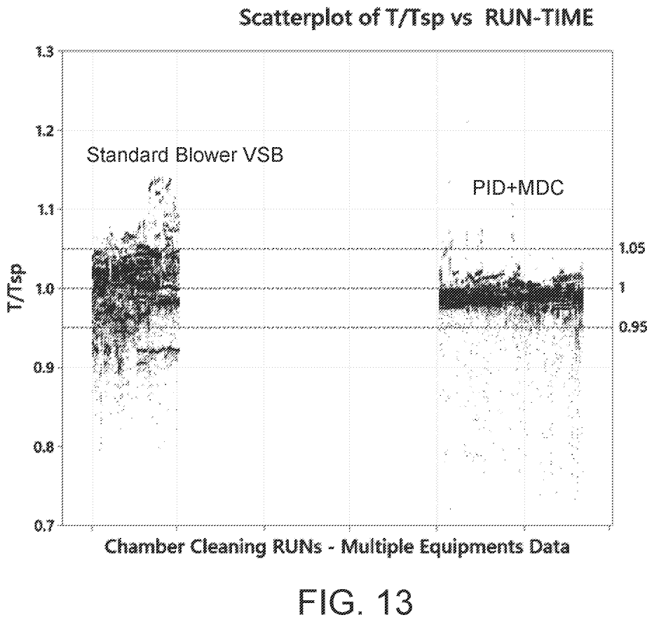

FIG. 11 shows boxplots of upper dome temperatures normalized to the setpoint temperature (T/Tₛₚ) collected from multiple reactors during a chamber cleaning step (left side set of plots) and a wafer processing (i.e., deposition) step (right side set of plots). The boxplots of normalized temperature from reactors using actuated damper and blower speed control according to the present disclosure (left plot of each set of plots) shows less variance during both the deposition step and chamber cleaning step than the boxplots of normalized temperature from reactors using standard variable blower speed control (right plot of each set of plots). FIGS. 12 and 13 show scatterplots of normalized temperature from the same reactors during a deposition step (FIG. 12) and a chamber cleaning step (FIG. 13). Similar to FIG. 11, FIGS. 12 and 13 show better control of the quartz upper wall temperatures during both the deposition step and the chamber cleaning step in reactors using actuated damper and blower speed control according to the present disclosure (right scatterplots) than in reactors using standard variable blower speed control (left scatterplots).

Accordingly, compared to conventional systems and methods for cooling a semiconductor reactor chamber, the systems and methods of the present disclosure facilitate improved temperature control of the upper wall during an entire epitaxial process. Advantageously, both the actuated damper and blower may be controlled based on a specific process step (and, optionally, based on a specific process or cleaning gas recipe). The combination of these components allows cooling fluid flow to be fine-tuned to meet a larger range of desired cooling conditions than systems or methods that only control one of these components.

The systems and methods of the present disclosure also provide the additional advantage of selectably controlling the cooling fluid flow provided individually to the upper and lower modules of a semiconductor wafer reactor where different cooling conditions are desired in each. For example, if decreased cooling conditions are desired in the upper modules during a chamber cleaning step, but not in the lower module, the systems and methods according to the present disclosure may be used to fine-tune the cooling fluid flow supplied to each (e.g., by diverting excess cooling fluid flow to lower module). This has the added advantage of improving the lifetime of lower module components which may otherwise unnecessarily be exposed to increased temperatures.

Further, the systems and methods of the present disclosure collect more real-time processing information to improve monitoring and fault detection within the semiconductor wafer reaction system. For example, using feedback from the damper actuator or blower (such as from a blower inverter), the controller may be configured to stop processing and/or indicate to a user that a desired temperature setpoint cannot be reached. Additional sensors (e.g., pressure sensors, temperature sensors, flow sensors) in communication with the controller also improve real-time monitoring and fault detection as described above. Conventional reactors include specific switches for air pressure (e.g., a pressure switch) and external chamber temperature (e.g., a thermal switch) in a safety circuit connected to the reactor. These passive components are used by the safety circuit to stop the reactor in the event of a detected problem. By including sensors to measure, for example, air pressure and air temperature, that are connected to the additional controller and host server, the signals are continuously monitored and can be used to predict passive sensors failure or malfunctioning.

When introducing elements of the present invention or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. An epitaxial reactor system for semiconductor wafer processing, the system comprising:
a reactor comprising:
a reaction chamber having an upper wall and a lower wall, the upper and lower walls defining an interior volume which receives a semiconductor wafer for epitaxy;
an upper module positioned above the upper wall of the reaction chamber; and
a lower module positioned below the lower wall of the reaction chamber;
a cooling circuit comprising:
a blower to circulate fluid within the upper module and the lower module;
a damper located downstream from the blower, wherein the damper is selectably positioned to control an amount of fluid flow provided to each of the upper module and the lower module; and
a damper actuator coupled to the damper that adjusts a position of the damper; and
a controller in communication with the blower and the damper actuator, the controller including a processor and a non-transitory memory storing instructions that, when executed by the processor, cause the controller to:
receive epitaxial process information associated with the reactor;
generate a blower output and a damper position output, each output generated based on the epitaxial process information;
transmit the blower output to the blower; and
transmit the damper position output to the damper actuator.

2. The system of claim 1, wherein the epitaxial process information received by the controller indicates a specific process step being performed in the reactor.

3. The system of claim 2, wherein the specific process step is one of a wafering process step and a chamber cleaning step.

4. The system of claim 2, wherein the epitaxial process information received by the controller indicates a specific gas recipe being used during the specific process step.

5. The system of claim 1, further comprising a temperature sensor connected to the controller, wherein the temperature sensor measures a temperature of the upper wall of the reaction chamber.

6. The system of claim 5, wherein the epitaxial process information includes information associated with a target temperature of the upper wall, and wherein the non-transitory memory of the controller stores instructions that, when executed by the processor, cause the controller to:
receive a measured temperature of the upper wall from the temperature sensor; and
generate, by comparing the measured temperature and the target temperature of the upper wall, an updated blower output.

7. The system of claim 6, wherein the updated blower output is generated using proportional-integral-derivative (PID) control.

8. The system of claim 1, wherein the damper position output causes the actuator to position the damper to a pre-determined position associated with the epitaxial process information.

9. A cooling system for a semiconductor wafer reactor, the reactor having a reaction chamber, an upper module, and a lower module, the cooling system comprising:
a cooling circuit comprising:
a blower to circulate a cooling fluid within the upper module and the lower module;
a damper located downstream from the blower, wherein the damper is selectably positioned to control an amount of fluid flow provided to each of the upper module and the lower module; and
a damper actuator coupled to the damper that adjusts a position of the damper; and
a controller in communication with the blower and the damper actuator, the controller including a processor and a non-transitory memory storing instructions that, when executed by the processor, cause the controller to:
receive epitaxial process information that indicates a specific process step being performed in the reactor;
generate a blower output and a damper position output, each output generated based on the epitaxial process information;
transmit the blower output to the blower; and
transmit the damper position output to the damper actuator.

10. The system of claim 9, wherein the specific process step is one of a wafering process step and a chamber cleaning step.

11. The system of claim 9, wherein the epitaxial process information received by the controller indicates a specific gas recipe being used during the specific process step.

12. The system of claim 9, wherein the damper position output causes the actuator to position the damper to a pre-determined position associated with the epitaxial process information.

13. The system of claim 9, further comprising a temperature sensor connected to the controller, wherein the temperature sensor measures a temperature of an upper wall of the reaction chamber.

14. The system of claim 13, wherein the non-transitory memory of the controller stores instructions that, when executed by the processor, cause the controller to:
determine, based on the epitaxial process information, a target temperature of the upper wall of the reaction chamber;
receive a measured temperature of the upper wall from the temperature sensor; and
generate, by comparing the measured temperature and the target temperature of the upper wall, an updated blower output.

15. The system of claim 14, wherein the updated blower output is generated using proportional-integral-derivative (PID) control.

16. The system of claim 14, wherein the non-transitory memory of the controller stores instructions that, when executed by the processor, cause the controller to:
receive a damper position feedback signal from the damper actuator;
receive a blower output feedback signal from the blower; and
generate the updated blower output using feedback control based on each of: a difference between the measured temperature and the target temperature of the upper wall, the damper position feedback signal, and the blower output feedback signal.

17. The system of claim 16, wherein the updated blower output is generated using proportional-integral-derivative (PID) control.

18. A method for cooling a semiconductor wafer reactor, the reactor having a reaction chamber, an upper module, and a lower module, the method comprising:
providing a blower to supply inlet streams of cooling fluid to each of the upper module and the lower module of the reactor;
providing a damper located downstream from the blower to control an amount of fluid flow in the inlet streams supplied to each of the upper module and the lower module;
receiving, by a controller, epitaxial process information associated with the reactor;
generating, by the controller, a blower output and a damper position output, each output generated based on the epitaxial process information;
transmitting, to the blower, the blower output; and
transmitting, to a damper actuator coupled to the damper, the damper position output.

19. The method of claim 18, further comprising receiving, by the controller from a temperature sensor connected to the controller, a temperature measurement of an upper wall of the reaction chamber.

20. The method of claim 19, further comprising:
determining, based on the epitaxial process information, a target temperature of the upper wall of the reaction chamber; and
generating an updated blower output based on a difference between the temperature measurement and the target temperature of the upper wall using proportional-integral-derivative (PID) control.
